(19) United States
(12) Patent Application Publication
(10) Pub. No.: US 2011/0186982 A1
(43) Pub. Date: Aug. 4, 2011

(54) SURFACE MOUNT DIODE AND METHOD OF FABRICATING THE SAME

(75) Inventors: Tomoyuki KITANI, Kanagawa-ken (JP); Akira TOJO, Kanagawa-ken (JP); Takao NOGI, Hyogo-ken (JP); Kazuhito HIGUCHI, Kanagawa-ken (JP); Tomohiro IGUCHI, Kanagawa-ken (JP); Masako FUKUMITSU, Kanagawa-ken (JP); Susumu OBATA, Kanagawa-ken (JP); Yusaku ASANO, Kanagawa-ken (JP)

(73) Assignee: KABUSHIKI KAISHA TOSHIBA, Tokyo (JP)

(21) Appl. No.: 13/016,239

(22) Filed: Jan. 28, 2011

(30) Foreign Application Priority Data
Jan. 29, 2010 (JP) 2010-019681

(51) Int. Cl. H01L 23/48; H01L 21/782

(52) U.S. Cl. 257/692; 438/113; 257/E23.01; 257/E21.599

(57) ABSTRACT

According to one embodiment, a surface mount diode including a diode chip including a first main surface and a second main surface, a cathode electrode including a first internal electrode portion on the first main surface and a first external electrode portion on the first internal electrode portion, an anode electrode including a second internal electrode portion on the second main surface and a second external electrode portion on the second internal electrode portion, a thickness of the second external electrode portion being the same as a thickness of the first external electrode portion, a first covering member covering a periphery surface of one of the internal electrode portions and a periphery surface of the diode chip, and a second covering member covering a periphery surface of the other of the internal electrode portions, the second covering member being different in color from the first covering member.

### CROSS REFERENCE TO RELATED APPLICATION

This application is based upon and claims the benefit of priority from prior Japanese Patent Application No. 2010-019681, filed on Jan. 29, 2010, the entire contents of which are incorporated herein by reference.

### FIELD

Exemplary embodiments described herein generally relate to a surface mount diode and a method of fabricating the surface mount diode.

### BACKGROUND

Recently, a surface mount diode includes an anode electrode and a cathode electrode which are arranged at one end and the other end of a rectangular parallelepiped package, respectively, for easily mounting on a circuit substrate. Further, the surface mount diode has been fabricated as a structure which can be mounted on any one of four side surfaces of the package.

However, the anode electrode and the cathode electrode are the same shape in the surface mount diode with such structure, so that identification between the both electrodes can be difficult. Therefore, when the diode is mounted on the circuit substrate, the anode electrode and the cathode electrode may be took wrong directions.

Accordingly, it is desirable that the anode electrode and the cathode electrode can be easily distinguished.

In conventional technology for the demand, the surface mount diode, which can easily distinguish the polarities of the anode electrode and the cathode electrode in appearance, has been proposed.

As shown in FIG. 5, a cathode electrode 103 and an anode electrode 104 are arranged at both ends in a rectangular parallelepiped package 102. One of the cathode electrode 103 and the anode electrode 104 is shaped as a concave 104a.

A surface of the anode electrode 104, for example, is shaped as the concave 104a, further the cathode electrode 103 and the anode electrode 104 are formed to have different thicknesses, respectively.

In the conventional surface mount diode, the anode electrode 104 having the concave 104a is generally formed by a press process. However, the surface mount diode has been downsized in recent years. Therefore, it is difficult to shape the concave 104a by the press process.

Furthermore, in mounting the surface mount diode 101 onto the circuit substrate, a side surface of the electrode is solder-bonded on the circuit substrate. However, a thickness of the cathode electrode 103 is different from that of the anode electrode 104, so that an area of a solder layer to the cathode electrode 103 is different from that to the anode electrode 104.

Therefore, the electrode with a thinner thickness may unstick from the circuit substrate, which is called tombstone phenomena, so that a connection failure may be generated at a junction portion.

### BRIEF DESCRIPTION OF THE DRAWINGS

FIG. 1 is a perspective view showing a surface mount diode according to an embodiment;

FIG. 2 is a cross-sectional view showing the surface mount diode along a line A-A in FIG. l according to the embodiment;

FIGS. 3A-3O are cross-sectional views showing a method of fabricating the surface mount diode according to the embodiment;

FIGS. 4A-4C are cross-sectional views showing a method of fabricating a surface mount diode according to a modification of the embodiment;

FIG. 5 is a schematic view showing a constitution of a conventional surface mount diode.

### DETAILED DESCRIPTION

In one embodiment, a surface mount diode including a diode chip including a first main surface and a second main surface which are opposite to each other, a cathode electrode including a first internal electrode portion on the first main surface and a first external electrode portion on a surface of the first internal electrode portion, an anode electrode including a second internal electrode portion on the second main surface and a second external electrode portion on a surface of the second internal electrode portion, a thickness of the second external electrode portion being the same as a thickness of the first external electrode portion, a first covering member covering a periphery surface of one of the first internal electrode portion and the second internal electrode portion, and a periphery surface of the diode chip, and a second covering member covering a periphery surface of the other of the first internal electrode portion and the second internal electrode portion, the second covering member being different in color from the first covering member.

Various embodiments will be described hereinafter below in detail with reference to the attached drawings. Throughout the attached drawings, similar or same reference numerals show similar, equivalent or same components.

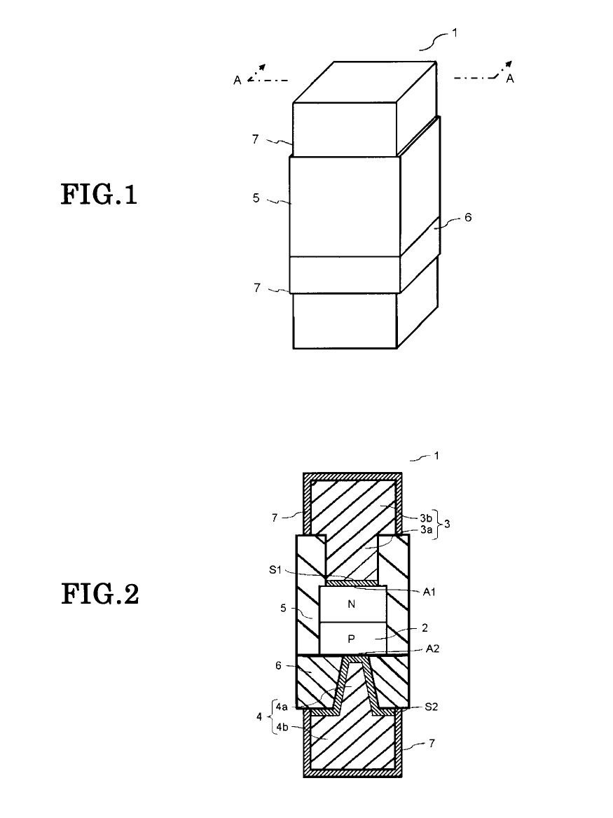

A surface mount diode and a method of fabricating the surface mount diode is explained below in detail according to an embodiment. First, the surface mount diode according to the embodiment is described with reference to FIG. 1 and FIG. 2.

As shown in FIG. 1 and FIG. 2, a surface mount diode 1 in this embodiment includes a diode chip 2, a cathode electrode 3, an anode electrode 4, a first covering member 5 and a second covering member 6, and has a rectangular parallelepiped shape as a structure in appearance.

The diode chip 2 has a first main surface A1 and a second main surface A2 which are opposite to each other. In this embodiment, an N-type layer is formed at a side of the first main surface A1, for example, and a P-type layer is formed at a side of a second main surface A2, for example, so as to create a PN-junction diode with a PN-junction between the N-type layer and the P-type layer.

The cathode electrode 3 is composed of a metal, for example, copper (Cu), and includes an internal electrode 3a and an external electrode 3b. The internal electrode portion 3a is formed on a first main surface A1 of the diode chip 2 via a seed layer S1. The external electrode portion 3b, which is formed on a surface of the internal electrode portion 3a, has a larger size than that of the internal electrode portion 3a and has a rectangular parallelepiped structure.

On the other hand, the anode electrode 4 is composed of a metal, Cu, as the same as the cathode electrode 3, and includes an internal electrode portion 4a and an external electrode portion 4b. The internal electrode portion 4a is formed on a second main surface A2 of the diode chip 2 via a second seed layer S2. The internal electrode portion 4a is formed as a tapered structure in which a side width of the external electrode portion 4b is larger than that of the second main surface A2 for easily forming the second seed layer S2. Furthermore, a size of the external electrode portion 4b is larger than a size of the internal electrode portion 4a. The external electrode portion 4b has a rectangular parallelepiped structure and is formed on a surface of the internal electrode portion 4a. A shape and a thickness of the external electrode portion 4b is formed to be nearly the same as those of the external electrode portion 3b of the cathode electrode 3.

The first covering member 5 is arranged to cover a periphery surface of the diode chip 2 and a periphery surface of the internal electrode 3a of the cathode electrode 3. The first covering member 5 is composed of thermosetting resin, for example, black epoxy resin in this embodiment. However, the first covering member 5 is not restricted to the example as mentioned above.

The second covering member 6 is contacted to the second main surface A2 of the diode chip 2 exposed at the side of the anode electrode 4 and the first covering member 5, and is arranged to cover a periphery surface of the internal electrode portion 4a. The second covering member 6 is composed of a photo sensitive resist which has a different color with the first covering member 5. In this embodiment, for example, the resist is composed of a developing type solder resist with white color, however, is not restricted to white color as long as the color is different from the color of the first covering member 5.

Further, a plating film 7 is formed to cover the periphery surface of the external electrode portions 3b, 4b of the cathode electrode 3 and the anode electrode 4, respectively. The plating film 7 is composed of nickel (Ni), tin (Sn) or the like, for example, to prevent oxidization of the electrode and improve solder wettability in mounting on the circuit substrate.

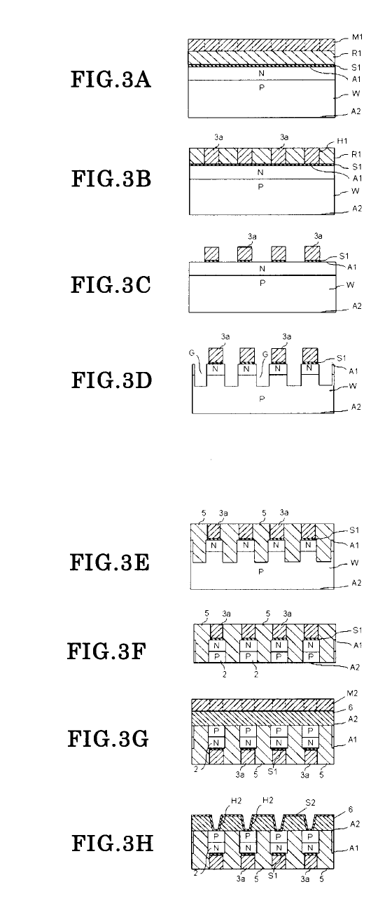

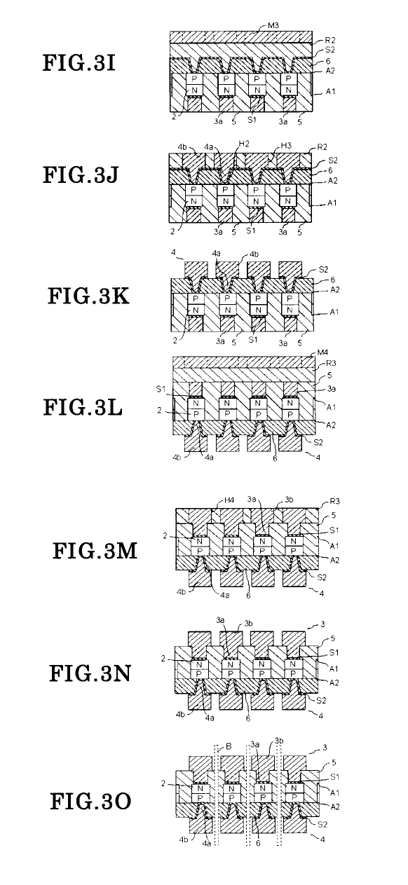

Next, a method of fabricating the surface mount diode 1, which has the structure mentioned above, is described using FIGS. 3A-3O. The method of fabricating the surface mount diode 1 includes forming a first internal electrode, forming a groove, forming a first covering member, separating a wafer to chips, forming a second covering member, forming a second electrode, forming a first external electrode and dividing the wafer into each chip.

As shown in FIG. 3A, a wafer W is prepared in forming the first internal electrode. The wafer W includes the first main surface A1 and the second main surface A2 which are opposite to each other, and includes a PN-junction between an N-type layer and a P-type layer which are formed at sides of the first main surface A1 and the second main surface, respectively. Next, a first seed layer S1 is formed entirely on a surface of the first main surface A1 in the wafer W, for example, by well-known sputtering, evaporation, nonelectrolytic plating or the like. A material of the first seed layer S1 can be selected in accordance with a material of the internal electrode 3a of the cathode electrode 3, for example, and is composed of Cu in this embodiment.

Next, a first resist R1 is entirely formed on a surface of the first seed layer S1, and a first mask M1 having a prescribed pattern is formed on the first resist R1. A dry film resist (DFR) with a film form, a resist with a liquid form or the like, for example, is used as the first resist R1, and DFR is used in this embodiment.

Successively, as shown in FIG. 3B, the first resist R1 is exposed and developed by well-known photolithography using the first mask M1 as a mask to form a plurality of first holes Hi which are spaced by a designated interval for forming the internal electrode portion 3a of the cathode electrode 3 in the first resist R1, so that each of the first holes H1 is exposed on a surface portion of the first seed layer S1.

After Cu is filled in the first holes H1 in the first resist R1 by well-known electrolytic plating, a planarization process is performed by well-known chemical mechanical polishing (CMP) to form the internal electrode portion 3a of the cathode electrode 3 having the same plane as the first resist R1 in the first holes H1.

Further, as shown in FIG. 3C, after removing the first resist R1, the first seed layer S1 between adjacent internal electrode portions 3a is removed by well-known wet etching, for example, using the internal electrode portion 3a as a mask. In such a manner, the adjacent internal electrode portions 3a in the cathode electrode 3 are separated. Further, the first seed layer S1 is removed by wet etching in this embodiment. However, the method is not limited to wet etching, dry etching may be also used.

As shown in FIG. 3D, a portion of the wafer W between adjacent internal electrode portions 3a is cut by a blade or the like, for example, till a prescribed depth to form grooves G in forming the grooves. Further, each depth of each groove G is over the PN-junction and is stopped before the second main surface A2 of the wafer W. In such a manner, the groove G is formed into nearly 250 μm depth for the wafer W with nearly 625 μm thickness in this embodiment.

In forming the first covering member, softened black epoxy resin is filled in the groove G and each void between the adjacent internal electrode portions 3a to resin-encapsulate periphery surfaces of the internal electrode portions 3a and the diode chip 2 by first covering member 5. As shown in FIG. 3E, the first covering member 5 is planarized by well-known CMP to form the same plane as the surface of the internal electrode portion 3a, so that the internal electrode portion 3a is exposed from the first covering member 5.

As shown in FIG. 3F, in separating the wafer into each chip, the side of the second main surface A2 in the wafer W is mechanically grinded, for example, by a grinder or the like to be separated into each diode chip 2 and is adjusted to a desirable thickness. In grinding, the wafer W is necessarily thinned to nearly a thickness which the first covering member 5 filled in the groove G is exposed. Since the thickness of the groove G is 250 μm, for example, in this embodiment, the diode chip 2 is grinded to a thickness of 200 μm. In such a manner, the wafer W is separated into each diode chip 2.

As shown in FIG. 3G, the second main surface A2 of the wafer W is set to be upward in forming the second covering member. The second covering member 6, for example, a white developing type solder resist is formed on the second main surface A2 of the diode chip 2 and a surface of the first covering member 5. A second mask M2 having a prescribed pattern is arranged on a surface of the second covering member 6.

As shown in FIG. 3H, the second covering member 6 is exposed and developed by well-known photolithography using the second mask M2 as a mask, so that second holes H2 are formed in the second covering member 6 for forming the internal electrode portion 4a of the anode electrode 4 to expose a portion of second main surface A2 of the diode chip 2. Each of the second hole H2 is formed to be tapered for improving adhesion to the internal electrode portion 4a. In the second hole H2, the bottom of the diode chip 2 is narrowed and the upper side of an opening end is widened. The second hole H2 with the tapered shape is formed by adjusting light strength of a laser, which is incident into the second covering member 6, to decrease with coming closer the side of the second main surface A2.

Next, in forming the second electrode, a second seed layer S2 is formed on a surface portion of the second main surface A2 of the diode chip 2 and a surface of the second covering member 6 exposed in the second hole H2 by well-known sputtering, evaporation, nonelectrolytic plating or the like, for example. A material of the second seed layer S2 can be selected in accordance with a material of the internal electrode 4a of the anode electrode 4, for example, and is composed of Cu in this embodiment.

As shown in FIG. 3I, a second resist R2 is formed on a surface of the second seed layer S2, and a third mask M3 having a prescribed pattern is formed on the second resist R2. A dry film resist (DFR) with a film form, a resist with a liquid form or the like, for example, is used as the second resist R2, and DFR is used in this embodiment. A material of the second resist R2 is different from a material of the second covering member 6. The reason is that the second covering member 6 is not simultaneously removed when the second resist R2 is removed.

As shown in FIG. 3J, the second resist R2 is exposed and developed by well-known photolithography using the third mask M3 as a mask, so that third holes H3 is formed in the second resist R2 for forming an external electrode portion 4b in the anode electrode 4. When the third hole H3 is formed, the second resist R2 in the second hole H2 is removed, so that the second hole H2 for forming the internal electrode portion 4a in the anode electrode 4 is communicated with the third hole H3 for forming the external electrode portion 4b.

After Cu is filled in the second holes H2 and the third holes H3 by well-known electrolytic plating, a planarization process is performed by well-known CMP to form the Cu surface in the third hole as the same plane as the second resist R2. In such a manner, the internal electrode portion 4a of the anode electrode 4 in the second holes H2 and the external electrode portion 4b of the anode electrode 4 in the third hole H3 are simultaneously formed.

As shown in FIG. 3K, after removing the second resist R2, the second seed layer S2 between the adjacent external electrode portions 4a is removed by wet etching using the external electrode portion 4b of the anode electrode 4 as a mask, so that the anode electrodes 4 adjacent to the diode chip 2 is electrically separated. In such the processing steps, the anode electrodes 4 are formed on the second main surface of the diode chip 2, respectively. Further, the method of etching the second seed layer S2 is not limited to wet etching as the same as the first seed layer S1. Dry etching may be used as the etching method, for example.

As shown in FIG. 3L, after a side of the internal electrode portion 3a of the cathode electrode 4 is set to be upward, which means the first main surface A1 of the diode chip 2 being upward, the third resist R3 is formed on the internal electrode portion 3a of the cathode electrode 3 and the first covering member 5 in forming the first external electrode. Further, a fourth mask M4 with a prescribed pattern is formed on the third resist R3.

As shown in FIG. 3M, the third resist R3 is exposed and developed by well-known photolithography using the fourth mask M4 as a mask, so that fourth holes H4 is formed in the third resist R3 for forming the external electrode portion 3b of the cathode electrode 3 to expose a surface of each internal electrode portion 3a of the cathode electrodes 3.

After Cu is filled in the fourth hole H4 by well-known electrolytic plating, the Cu surface is planarized by well-known CMP, so that Cu in each fourth hole H4 is form to be the same plane as the third resist R3. In such a manner, each external electrode portion 3b is formed in a surface of the internal electrode portion 3a of each cathode electrode 3.

As shown in FIG. 3N, the cathode electrode 3 including the internal electrode portion 3a and the external electrode portion 3b is obtained by removing the third resist R3.

As shown in FIG. 3O, the first covering member 5 and the second covering member 6 between adjacent diodes with the cathode electrode 3 and the anode electrode 4 are cut to be separated by a blade B, for example, so that fabricating the surface mount diode 1 as shown in FIG. 1 and FIG. 2 is completed in separating the wafer into each chip. Further, when a width of the blade B is the same as a width between the external electrode portions 3b and 4b of the cathode electrode 3 and the anode electrode 4, respectively, the external electrode portion is damaged. Accordingly, the blade B with the width being narrower than that of the external electrode portion is used.

As shown in FIG. 2, the plating film 7 is formed on each surface of the external electrode portions 3b and 4b of the cathode electrode 3 and the anode electrode 4 in separated surface mount diode 1, respectively, by well-known barrel plating, for example, in electrolytic plating.

Furthermore, the plating film 7 in this embodiment is formed after dividing the wafer into the surface mount diode 1. However, the plating film can be formed before dividing. In response to a solder failure in mounting on the circuit substrate due to a step between each side surface of the first and the second covering members 5, 6 and each side surface of the external electrode portions 3b, 4b in the cathode electrode 3 and the anode electrode 4, respectively, the step being generated in cutting and separating, it is capable of planarizing the surface by adjusting the thickness of the plating film 7, or forming the side surfaces of the external electrode portions 3b, 4b which are positioned slightly outside to the side surfaces of the first and second covering members 5, 6.

The internal electrode portion 4a of the anode electrode 4 is covered with the white second covering member 6 which is different from the black first covering member 5 of the internal electrode portion 3a of the cathode electrode 3 in the surface mount diode according to the embodiment. Therefore, the polarity is easily distinguished as the white side being the anode electrode 4 and the black side being the cathode electrode 3 in appearance. Further, the thickness of the external electrode portion 3b of the cathode electrode 3 is the same as the thickness of the external electrode portion 4b of the anode electrode 4. As a result, in mounting on the circuit substrate, an area of the solder layer of the cathode electrode 3 is the same as the area of the solder layer of the anode electrode 4, so that tombstone phenomena can be prevented.

While certain embodiments have been described, these embodiments have been presented byway of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

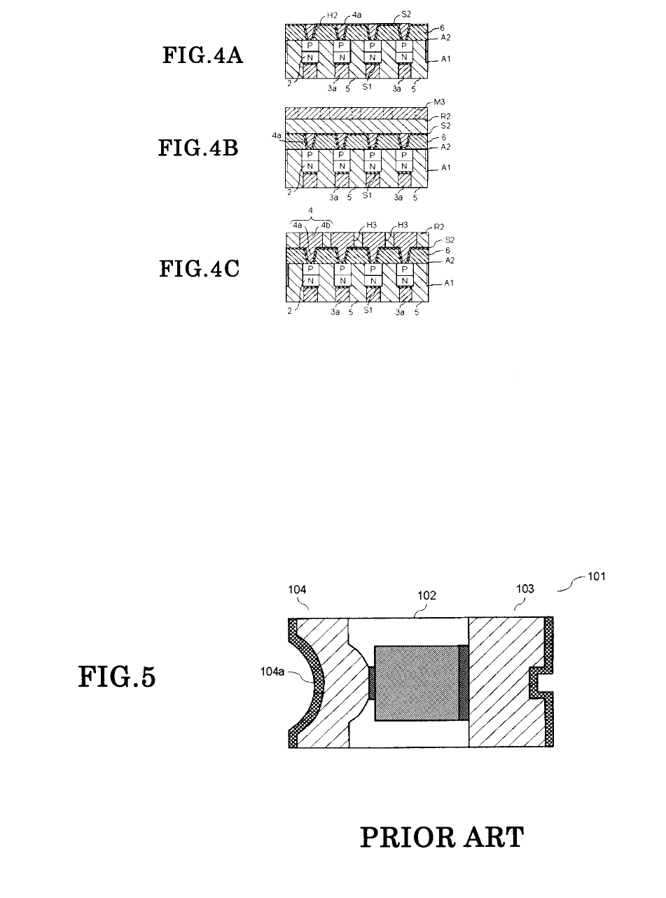

As a modification, for example, the internal electrode portion 4a and the external electrode portion 4b in the anode electrode 4 are simultaneously formed in the same process in the embodiment. However, another process can be used as shown in FIGS. 4A-4C as a modification of the embodiment mentioned below. After forming the second seed layer S2 as shown in FIG. 3H in the embodiment, Cu is filled in the second holes H2 as shown in FIG. 4A. Subsequently, Cu is planarized, so that the internal electrode portion 4a is formed. As shown in FIG. 4B, the second resist R2 is formed on the internal electrode portion 4a. Successively, the second seed layer S2 is formed on the second covering member 6 and the third mask M3 having the prescribed pattern is arranged on the second resist R2.

As shown in FIG. 4C, the second resist R2 is exposed and developed by well-known photolithography using the third mask M3 as a mask, so that the third holes H3 for forming the external electrode portion 4b of the anode electrode 4 are formed in the second resist R2 to expose the internal electrode portion 4a of the anode electrode 4 and a portion of the second covering member 6 near there.

After Cu is filled in the third holes H3 by well-known electrolytic plating, the cu layer is planarized by well-known CMP, so that the Cu surface in the third holes H3 are formed as the same plane as that of the second resist R2. In such a manner, the external electrode portion 4b of the anode electrode 4 is formed on the surface of the internal electrode portion 4a. Next, the processing steps below FIG. 3K are identical with the steps in the embodiment.

According to the semiconductor of at least the embodiments described above, a surface mount diode which can be distinguished on the polarity in appearance and the method of fabricating the diode without generation of tombstone phenomena can be provided.

The diode is not limited to the PN-junction diode in this embodiment. For example, a PIN type, a schottky-junction type, a zener type or the like can be applied to the surface mount diode.

What is claimed is:

1. A surface mount diode comprising:
a diode chip including a first main surface and a second main surface which are opposite to each other;
a cathode electrode including a first internal electrode portion on the first main surface and a first external electrode portion on a surface of the first internal electrode portion;
an anode electrode including a second internal electrode portion on the second main surface and a second external electrode portion on a surface of the second internal electrode portion, a thickness of the second external electrode portion being the same as a thickness of the first external electrode portion;
a first covering member covering a periphery surface of one of the first internal electrode portion and the second internal electrode portion, and a periphery surface of the diode chip; and
a second covering member covering a periphery surface of the other of the first internal electrode portion and the second internal electrode portion, the second covering member being different in color from the first covering member.

2. The surface mount diode of claim 1, wherein
the other internal electrode portion has a tapered shape in which a width at a diode side is narrower than a width at an external electrode portion side.

3. The surface mount diode of claim 1, wherein
the first covering member is composed of black thermosetting resin and the second covering member is composed of white resist.

4. The surface mount diode of claim 2, wherein
the first covering member is composed of black thermosetting resin and the second covering member is composed of white resist.

5. A method of fabricating a surface mount diode, comprising:
forming a plurality of first internal electrode portions, each of the first internal electrode portions being arranged in one of a cathode electrode and an anode electrode on a first main surface of a wafer including a second main surface being opposite to the first main surface and being spaced by an interval;
forming grooves, each groove being arranged between adjacent first internal electrodes in the wafer;
forming a first covering member in the grooves and each portion between adjacent first internal electrode portions;
removing a portion of the wafer at a side of the second main surface to separate the wafer into each diode chip;
forming a second covering member on the second main surface and a surface of the first covering member in the diode chip, the second covering member having holes exposing a portion of the second main surface and being different in color from the first covering member;
forming a plurality of second internal electrode portions in the second covering member, each of the second internal electrode portions being arranged in the other of the cathode electrode and the anode electrode;
forming a second external electrode portion on the second internal electrode portion;
forming a first external electrode portion on the first internal electrode portion, the first external electrode portion having a same thickness as a thickness of the second external electrode portion; and
cutting the first covering member and the second covering member between adjacent diode chips into each surface mount diode.

6. The method of claim 5, wherein
forming the second internal electrode and forming the second external electrode are performed in a same process.

7. The method of claim 5, wherein
the second internal electrode portion is formed to be tapered, a width at a side of the diode chip is narrower than a width at a side of the second external electrode portion.

8. The method of claim 6, wherein
the second internal electrode portion is formed to be tapered, a width at a side of the diode chip is narrower than a width at a side of the second external electrode portion.
